(19) United States
(12) Patent Application Publication
(10) Pub. No.: US 2009/0297978 A1
(43) Pub. Date: Dec. 3, 2009

(54) Method of Forming Exposure Visualization Image of Planographic Printing Plate Material, Aluminum Support, and Planographic Printing Plate Material

(76) Inventor: Tomonori Kawamura, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/883,066

(22) PCT Filed: Jan. 13, 2006
(86) PCT No.: PCT/JP06/00332

§ 371 Date: Jul. 26, 2007

(30) Foreign Application Priority Data
Jan. 31, 2005 (JP) 2005-022520

(51) Int. Cl. G03F 7/20; G03F 7/004

(52) U.S. Cl. 430/270.1; 430/302

(57) ABSTRACT

An objective is to provide a method of forming an exposure visualization image of a planographic printing plate material in which printing of the planographic printing plate material is capable of on-press printing, and also provided excellent plate inspection together with excellent color reproduction and excellent printing durability. Disclosed is a method of forming an exposure visualization image of a planographic printing plate material possessing the step of imagewise exposing the planographic printing plate material possessing an aluminum support having anodization film pores on a surface of the aluminum support and provided thereon, an image formation layer to form the visualization image, wherein the aluminum support posseses a colorant producing color change via heat, in the anodization film pores.

### TECHNICAL FIELD

The present invention relates to a planographic printing plate material and a method of forming an exposure visualization image thereof, and specifically to a method of forming an exposure visualization image of a planographic printing plate material capable of forming an image via a computer to plate (CTP) system.

### BACKGROUND

Presently, printing employing a CTP system has been conducted in printing industries, accompanied with the digitization of printing data. A printing plate material for CTP, which is inexpensive, can be easily handled, and has printability comparable with that of a PS plate, is desired.

Particularly in recent years, a printing plate material has been sought which does not require any development employing a developer containing specific chemicals (such as alkalis, acids, and solvents), and can be applied to a conventional printing press. Known are a chemical-free type printing plate material such as a phase change type printing plate material requiring no development process, a printing plate material which can be processed with water or a neutral processing liquid comprised mainly of water, or a printing plate material capable of being developed on a printing press at initial printing stage and requiring no development process; and a printing plate material called a processless printing plate material.

A printing plate material requiring no development process or a processless printing plate material to be developed on a plate cylinder of a printing press is required to provide an exposure visualization property similarly to a conventional PS, since it is punched after imagewise exposure to form holes for mounting on the plate cylinder.

Further, a processless printing plate material is imagewise exposed employing an infrared laser with an emission wavelength of from near-infrared to infrared regions to form an image. The thermal processless printing plate material employing this method is divided into the following known types: an ablation type printing plate material, a development-on-press type printing plate material with a heat melting image formation layer, and a phase change type printing plate material.

Also known is the following printing plate material such as a processless printing plate material having an exposure visualization property.

Examples of commonly known printing plate materials include a printing plate material having a layer containing a thermo-sensitively coloring material such as a leuco dye and a color developing agent in an image formation layer or a lipophilic oil layer containing a compound colored by a functional polymeric compound generating a sulfonic acid or a generated acid via heating (refer to Patent Documents 1 and 2), a printing plate material having a layer containing an IR-dye capable of varying optical density by exposing image formation elements (refer to Patent Document 3), and a printing plate material having a hydrophilic overcoat layer removable on a printing press, which contains at least 20% by weight of a cyanine infrared absorbing dye capable of varying optical density by light exposure (refer to Patent Document 4).

However, it is seen as a problem that dyes are sublimed or scattered via laser exposure during image formation since these printing plate materials contain these dyes resulting in coloring, discoloring, or color-fading in an image formation layer via light exposure. There is also a problem such that it is difficult to avoid contamination to printing ink as well as dampening water, caused by these dyes, and a large amount of paper waste is consumed to the point where a normal printing paper sheet is obtained during development-on-press.

Since a light-to-heat conversion material and a coloring or discoloring material are dispersed in constituting layers of these printing plate materials, insufficient sensitivity and on-press developability of a printing plate material are also exhibited in the case of acquiring sufficient exposure visualization, resulting in difficulty in balancing printability with exposure visualization.

It is also known that a metal formed from electrolytic coloring is deposited in pores of anodization, and this is utilized as a light-to-heat conversion material for a printing plate material (refer to Patent Document 5), but an exposure visualization image was hardly possible to be obtained. A photosensitive planographic printing plate material in which the surface of an aluminum support is colored with a dye is also known (refer to Patent Document 6), but an exposure visualization image was also hardly possible to be obtained.

(Patent Document 1) Japanese Patent O.P.I. Publication No. 2000-225780

(Patent Document 2) Japanese Patent O.P.I. Publication No. 2002-211150

(Patent Document 3) Japanese Patent O.P.I. Publication No. 11-240270

(Patent Document 4) Japanese Patent O.P.I. Publication No. 2002-205466

(Patent Document 5) Japanese Patent O.P.I. Publication No. 2000-267291

(Patent Document 6) Japanese Patent O.P.I. Publication No. 7-333831

### DISCLOSURE OF THE INVENTION

It is an object of the present invention to provide a method of forming an exposure visualization image of a planographic printing plate material in which printing employing the planographic printing plate material is capable of developing on a printing press, and also providing a printing process exhibiting excellent plate inspection together with excellent color reproduction and excellent printing durability.

The above object of the present invention is accomplished by the following structures.

(Structure 1) A method of forming an exposure visualization image of a planographic printing plate material comprising the step of imagewise exposing the planographic printing plate material comprising an aluminum support having anodization film pores on a surface of the aluminum support and provided thereon, an image formation layer to form the visualization image, wherein the aluminum support comprises a colorant producing color change via heat, in the anodization film pores.

(Structure 2) The method of Structure 1, wherein the aluminum support further comprises a light-to-heat conversion material in the anodization film pores.

(Structure 3) The method of Structure 2, wherein a sealing treatment is conducted after containing the colorant and the light-to-heat conversion material in the anodization film pores.

(Structure 4) The method of any one of Structures 1-3, wherein the image formation layer is a thermosensitive image formation layer.

(Structure 5) The aluminum support utilized for the method of any one of Structures 1-4.

(Structure 6) The planographic printing plate material utilized for the method of any one of Structures 1-4.

### DESCRIPTION OF THE PREFERRED EMBODIMENTS

In the present invention, it is a feature that provided is a method of forming an exposure visualization image of a planographic printing plate material comprising the step of imagewise exposing the planographic printing plate material comprising an aluminum support having anodization film pores on a surface of the aluminum support and provided thereon, an image formation layer to form the visualization image, wherein the aluminum support comprises a colorant producing color change via heat, in the anodization film pores.

In the present invention, use of an aluminum support comprising a colorant producing color change via heat, in anodization film pores can provide a printing method exhibiting an excellent exposure visualization property, excellent plate inspection together with excellent color reproduction coupled with no printing ink contamination and excellent printing durability.

### (Aluminum Support)

The support of the present invention is capable of carrying an image formation layer, and an aluminum plate is used as the support.

The usable aluminum plate is an aluminum plate or an aluminum alloy plate.

As the aluminum alloy, there can be used various ones including an aluminum alloy and a metal such as silicon, copper, manganese, magnesium, chromium, zinc, lead, bismuth, nickel, titanium, sodium or iron.

The aluminum support of the present invention has been subjected to an anodization treatment, and the support surface comprises anodization film pores generated during the anodization treatment.

In the present invention, the aluminum support comprises a colorant producing color change via heat, in the pores.

It is preferable that the aluminum support is subjected to a degreasing treatment and a surface roughening treatment for removing rolling oil prior to an anodization treatment.

The degreasing treatments include a degreasing treatment employing solvents such as trichlene and thinner, and an emulsion degreasing treatment employing an emulsion such as kerosene or triethanol.

It is also possible to use an aqueous alkali solution such as an aqueous solution of sodium hydroxide, potassium hydroxide, sodium carbonate, or sodium phosphate for the degreasing treatment. When such an aqueous alkali solution is used for the degreasing treatment, it is possible to remove stain and an oxidized film which can not be removed by the above-mentioned degreasing treatment alone.

When the aqueous alkali solution is used for the degreasing treatment, the resulting plate is preferably subjected to neutralization treatment in an aqueous solution of an acid such as phosphoric acid, nitric acid, sulfuric acid, chromic acid or a mixed acid thereof.

The electrolytic surface roughening after the neutralization is carried out preferably in the same acid solution as in the neutralization treatment.

The electrolytic surface roughening treatment is carried out according to a known method, but prior to that, chemical surface roughening treatment and/or mechanical surface roughening treatment may be carried out. The mechanical surface roughening treatment is preferably carried out.

The chemical surface roughening treatment is carried out employing an aqueous alkali solution such as an aqueous solution of sodium hydroxide, potassium hydroxide, sodium carbonate, or sodium phosphate in the same manner as in degreasing treatment above.

After that, the resulting plate is preferably subjected to neutralization treatment in an aqueous solution of an acid such as phosphoric acid, nitric acid, sulfuric acid, chromic acid or a mixed acid thereof. The electrolytic surface roughening after the neutralization is carried out preferably in the same acid solution as in the neutralization treatment.

Though there is no restriction for mechanical surface roughening, a brushing roughening method and a honing roughening method are preferable.

After the substrate has been roughened mechanically, it is preferably dipped in an acid or an aqueous alkali solution in order to remove abrasives and aluminum dust, etc. which have been embedded in the surface of the substrate or to control the shape of pits formed on the plate surface, whereby the surface is etched.

Examples of the acid include sulfuric acid, persulfuric acid, hydrofluoric acid, phosphoric acid, nitric acid and hydrochloric acid, and examples of the alkali include sodium hydroxide and potassium hydroxide.

In the present invention, the aluminum plate was mechanically surface roughened with an abrasive with a particle size of not less than #400, followed by etching treatment employing an aqueous alkali solution, whereby a complex surface structure formed due to the mechanical surface roughening treatment can be changed to a surface having a smooth roughened structure.

The resulting plate after dipped in the aqueous alkali solution is preferably subjected to neutralization treatment in an aqueous solution of an acid such as phosphoric acid, nitric acid, sulfuric acid, chromic acid or the mixed acid thereof.

The electrolytic surface roughening after the neutralization is preferably carried out in the same acid solution as in the neutralization treatment.

The electrolytic surface roughening treatment in the present invention is carried out in an acidic electrolytic solution employing an alternating current. As the acidic electrolytic solution, an acidic electrolytic solution used in a conventional electrolytic surface roughening treatment can be used, but a hydrochloric acid or nitric acid electrolytic solution is preferably used. In the present invention, a hydrochloric acid electrolytic solution is especially preferably used.

As a current waveform used in the electrolytic surface roughening treatment, various waveforms such as a rectangular wave, trapezoidal wave, sawtooth wave or sine wave can be used, but sine wave is preferably used.

Separated electrolytic surface roughening treatments disclosed in Japanese Patent O.P.I. Publication No. 10-869 are also preferably used.

In the electrolytic surface roughening treatment carried out using an electrolytic solution of nitric acid, voltage applied is preferably 1-50 V, and more preferably 5-30 V.

The current density (in terms of peak value) used is preferably 10-200 A/dm², and more preferably 20-150 A/dm².

The total quantity of electricity is preferably 100-2000 C/dm², more preferably 200-1500 C/dm², and most preferably 200-1000 C/dm².

Temperature during the electrolytic surface roughening treatment is preferably 10-50° C., and more preferably 15-45° C. The nitric acid concentration in the electrolytic solution is preferably 0.1-5% by weight.

It is possible to optionally add, into the electrolytic solution, nitrates, chlorides, amines, aldehydes, phosphoric acid, chromic acid, boric acid, acetic acid or oxalic acid.

In the present invention, the electrolytically surface roughened aluminum support is dipped and subjected to etching treatment in an aqueous alkali solution in order to remove smuts produced on the plate surface, or to control the shape of pits formed on the plate surface, whereby the surface is etched.

Examples of the alkali solution include a sodium hydroxide solution, a potassium hydroxide solution, a sodium carbonate solution, or a sodium phosphate solution.

The etching treatment employing the alkali solution is preferable in view of initial printability and background contamination.

The resulting support after dipped in the aqueous alkali solution in the above is preferably subjected to neutralization treatment in an aqueous solution of an acid such as phosphoric acid, nitric acid, sulfuric acid, chromic acid, or the mixed acid thereof. The anodization treatment after the neutralization treatment is carried out preferably in the same acid solution as in the neutralization treatment.

The aluminum support has been subjected to the surface roughening treatment, followed by an anodization treatment.

There is no restriction in particular for an anodization treatment method used in the present invention, and known methods are usable.

The anodization treatment forms an anodization film having pores on the surface of the aluminum substrate. Further, aluminum turns to aluminum oxide via the anodization treatment to form an oxidized film, and a porous film is formed in a process of growing the oxidized film. In addition, A diameter of the pores is 100-400 A.

For the anodization treatment in the present invention there is preferably used a method of carrying out electrolysis by applying a current density of 1-10 A/dm² to an aqueous solution containing sulfuric acid and/or phosphoric acid in a concentration of 10-50%, as an electrolytic solution. However, it is also possible to use a method of carrying out electrolysis by applying a high current density to sulfuric acid as described in U.S. Pat. No. 1,412,768, or a method of carrying out electrolysis in phosphoric acid as described in U.S. Pat. No. 3,511,661.

The colorant of the present invention producing color change thermally is a colorant producing color change via heat generated during exposure, and the color change means changing of maximal absorption wavelength (λmax), or changing of λmax absorbance.

The former change is mainly accompanied with change of hue or saturation, and the latter change is mainly accompanied with change of brightness. The desired change of λmax depends on color and density of a colorant before changing, but it is preferably 20-300 nm, and the amount of desired change in λmax absorbance is preferably 5-95%.

Dyes employed for coloring an anodization film are usable as the colorant, and examples thereof include TAC YELLOW-SLH (trade name), TAC YELLOW-RBL, TAC YELLOW-RHM, TOP SHUTETSUAN, TAC ORANGE-SLH, TAC ORANGE-LH, TAC ORANGE-CH, TAC ORANGE-TCH, TAC RED-GD, TAC FIERY RED-GBM, TAC RED-SCH, TAC RED-BLH, TAC VIOLET-SLH, TAC SKYBLUE-GLH, TAC BLUE-SLH, TAC BLUE-RCD, TAC GREEN-GM, TAC GREEN-SBM, TAC BRONZE-GM, TAC BROWN-GR, TAC BROWN-RH, TAC BLACK-GLH, TAC BLACK-GRLH, TAC BLACK-SG, TAC BLACK-LSH, TAC BLACK-GBLH, TAC BLACK-GNB, TAC BLACK-NBLH, TAC BLACK-BLH and TOP ADD-500 (produced by Okuno Chemical Industries Co., Ltd.).

In order to contain a colorant in pores, an aluminum support subjected to an anodization treatment is immersed in a colorant-containing solution in which the colorant is dissolved or dispersed, and is colored with a dye to contain the colorant in anodization film pores.

The content of the colorant in a solution containing the colorant is preferably within the range of 0.1-10 g/liter, and pH of this solution is preferably within the range of 4.0-7.0.

It is preferable that an aluminum support is sufficiently washed with water to remove dissolved aluminum, dissolved sulfate radical and so forth before coloring with a dye as described above.

The aluminum support containing a colorant via the anodization treatment may be optionally subjected to sealing treatment.

For the sealing treatment, it is possible to use known sealing treatment carried out using hot water, boiling water, steam, an aqueous dichromate solution, a nitrite solution and an ammonium acetate solution.

The substrate subjected to the anodization treatment may be subjected to a surface treatment other than the sealing treatment.

Examples of the surface treatment include known treatments such as silicate treatment, phosphate treatment, various organic acid treatment, PVPA treatment and boehmite treatment. Further, the aluminum plate subjected to anodization treatment may be subjected to surface treatment disclosed in Japanese Patent O.P.I. Publication No. 8-314157 in which the aluminum plate is treated in an aqueous bicarbonate solution or the aluminum plate is treated in an aqueous bicarbonate solution, followed by treatment in an organic acid solution such as an aqueous citric acid solution.

The thickness of the aluminum support is not particularly limited provided that the support is installable in a printing press, but a thickness of 50-500 μm can easily be handled.

### (Light-to-Heat Conversion Material)

In the present invention, a light-to-heat conversion material is preferably contained in anodization film pores in view of a visualization property and color reproduction.

Presumably, a color change efficiency of a colorant is improved since the colorant is located close to a light-to-heat conversion material, and prevention of printing ink contamination is caused by further fixing the colorant in the pores.

A light-to-heat conversion material is capable of generating heat via imagewise exposure, and examples thereof include infrared absorbing dyes, pigments and so forth.

Examples of the infrared absorbing dye include organic compounds as conventional infrared absorbing dyes such as cyanine based dyes, chloconium based dyes, polymethine based dyes, azulenium based dyes, aqualenium based dyes, thiopyrylium based dyes, naphthoquinone based dyes and anthraquinone based dyes, and organometallic complexes such as phthalocyanine based complexes, naphtalocyanine based complexes, azo based complexes, thioamide based complexes, dithiol based complexes and indoanyline based complexes.

Examples of the pigment include carbon, graphite, metal and metal compounds.

A light-to-heat conversion material can be precipitated in pores via immersion in a solution containing the light-to-heat conversion material to adsorb it.

In the present invention, metal or a compound containing metal is preferably employed as a light-to-heat conversion material. The metal or the compound containing metal generated in anodization film pores are obtained specifically by conducting an electrolysis treatment in an electrolyte containing metal ions, and is preferable in view of color reproduction and a visualization property.

Examples of the electrolysis treatment include a process of conducting an alternating current electrolysis treatment of an anodization film in an electrolyte containing a metal (Ni, Cu, Se or Sn) salt, and a process of conducting a direct current electrolysis treatment in an electrolyte containing a metal (Ni or such) salt.

When a light-to-heat conversion material generated via the electrolysis treatment is used, the electrolysis treatment, followed by a process of containing the above-described colorant is preferable. Subsequently, further, a sealing treatment is preferably conducted in the case of performing the sealing treatment.

That is, it is preferable to utilize a method of forming an exposure visualization image of a planographic printing plate material of the foregoing Structure 2, wherein a sealing treatment is conducted after containing the colorant and the light-to-heat conversion material in the anodization film pores.

(Image Formation Layer Capable of on-Press Developing)

The image formation layer of the present invention is a layer formed via imagewise exposure, and is preferably an image formation layer capable particularly of on-press developing.

The image formation layer capable of on-press developing means an image formation layer capable of forming a printable image via removal of the image formation layer in which the portion becomes a non-image portion during printing employing dampening water, or dampening water and printing ink in the preparatory stage of printing, that is, at a time when the image formation layer is subjected to a printing process particularly with no developing treatment after imagewise exposure.

The thermosensitive image formation layer is a thermosensitive image formation layer capable of forming an image via heat generation of a layer containing a light-to-heat conversion material by which image wise exposure light is converted into heat.

A layer comprising a light-to-heat conversion material may be an image formation layer of the present invention, or may be a hydrophilic layer or another layer adjacent to a thermosensitive image formation layer.

An image formation layer at an exposure portion is moved and changed in the direction in which it is firmly fixed onto the hydrophilic layer via heat, and this so-called negative type image formation layer is preferably used.

The image formation layer at an exposure portion changed in the direction in which it is firmly fixed onto the hydrophilic layer via heat can be, for example, an image formation layer containing a hydrophobe precursor capable of changing from a layer exhibiting hydrophilicity (hydrophilic layer before exposure) to a layer exhibiting hydrophobicity.

Microcapsules encapsulating a hydrophobic material or thermoplastic hydrophobic particles such as heat melting particles or heat fusible particles, and blocked isocyanate compounds are preferably used as the hydrophobe precursor, and there is, for example, a polymer whose property is capable of changing from a hydrophilic property (a water dissolving property or a water swelling property) or to a hydrophobic property by heating. Specifically, examples of the hydrophobe precursor include a polymer having an aryldiazosulfonate unit as disclosed in for example, Japanese Patent O.P.I. Publication No. 2000-56449.

As the above-described thermoplastic hydrophobic particles, there are heat melting particles or heat fusible particles, as described later.

The heat melting particles used in the present invention are particularly particles having a low melt viscosity, which are particles formed from materials generally classified into wax. The materials preferably have a softening point of 40-120° C. and a melting point of 60-150° C., and more preferably a softening point of 40-100° C. and a melting point of 60-120° C. The melting point less than 60° C. has a problem in storage stability and the melting point exceeding 300° C. lowers ink receptive sensitivity.

Materials usable include paraffin, polyolefin, polyethylene wax, microcrystalline wax, and fatty acid wax. The molecular weight thereof is approximately from 800 to 10,000. A polar group such as a hydroxyl group, an ester group, a carboxyl group, an aldehyde group and a peroxide group may be introduced into the wax by oxidation to increase the emulsification ability. Moreover, stearoamide, linolenamide, laurylamide, myristylamide, hardened cattle fatty acid amide, parmitylamide, oleylamide, rice bran oil fatty acid amide, palm oil fatty acid amide, a methylol compound of the above-mentioned amide compounds, methylenebissteastearoamide and ethylenebissteastearoamide may be added to the wax to lower the softening point or to raise the working efficiency. A cumarone-indene resin, a rosin-modified phenol resin, a terpene-modified phenol resin, a xylene resin, a ketone resin, an acryl resin, an ionomer and a copolymer of these resins may also be usable.

Among them, polyethylene, microcrystalline wax, fatty acid ester and fatty acid are preferably contained. A high sensitive image formation can be performed since these materials each have a relative low melting point and a low melt viscosity.

The heat fusible particles in the invention include thermoplastic hydrophobic polymer particles. Although there is no specific limitation to the upper limit of the softening point of the thermoplastic hydrophobic polymer, the softening point is preferably lower than the decomposition temperature of the polymer. The weight average molecular weight (Mw) of the thermoplastic hydrophobic polymer is preferably within the range of 10,000-1,000,000.

Examples of the polymer constituting the polymer particles include a diene (co)polymer such as polypropylene, polybutadiene, polyisoprene or an ethylene-butadiene copolymer; a synthetic rubber such as a styrene-butadiene copolymer, a methyl methacrylate-butadiene copolymer or an acrylonitrile-butadiene copolymer; a (meth)acrylate (co)polymer or a (meth)acrylic acid (co)polymer such as polymethyl methacrylate, a methyl methacrylate-(2-ethylhexyl)acrylate copolymer, a methyl methacrylate-methacrylic acid copolymer, or a methyl acrylate-(N-methylolacrylamide); polyacrylonitrile; a vinyl ester (co)polymer such as a polyvinyl acetate, a vinyl acetate-vinyl propionate copolymer and a vinyl acetate-ethylene copolymer, or a vinyl acetate-2-hexylethyl acrylate copolymer; and polyvinyl chloride, polyvinylidene chloride, polystyrene and a copolymer thereof. Among them, the (meth)acrylate polymer, the (meth)acrylic acid (co)polymer, the vinyl ester (co)polymer, the polystyrene and the synthetic rubbers are preferably used.

### [Blocked Isocyanate Compound]

The blocked isocyanate compound is a compound obtained by addition reaction of an isocyanate compound with a blocking agent described below.

The blocked isocyanate compound used in the image formation layer is preferably in the form of aqueous dispersion of a compound described below.

Coating of the aqueous dispersion provides good on-press developability.

### [Isocyanate Compound]

Examples of the isocyanate compound include an aromatic polyisocyanate such as diphenylmethane diisocyanate (MDI), tolylene diisocyanate (TDI), polyphenylpolymethylene polyisocyanate (crude MDI), or naphthalene diisocyanate (NDI); an aliphatic polyisocyanate such as 1,6-hexamethylene diisocyanate (HDI), or lysine diisocyanate (LDI); an alicyclic polyisocyanate such as isophorone diisocyanate (IPDI), dicyclohexylmethane diisocyanate (hydrogenation MDI), or cyclohexylene diisocyanate; an aromatic aliphatic Polyisocyanate such as xylylene diisocyanate (XDI), or tetramethylxylene diisocyanate (TMXDI); and their modified compounds such as those having a burette group, an isocyanurate group, a carbodiimide group, or an oxazolidine group); and a urethane polymer having an isocyanate group in the molecular end, which is comprised of an active hydrogen-containing compound with a molecular weight of from 50 to 5,000 and the polyisocyanate described above.

### [Blocking Material]

Examples of the blocking material include an alcohol type blocking material such as methanol, or ethanol; a phenol type blocking material such as phenol or cresol; an oxime type blocking material such as formaldoxime, acetaldoxime, methyl ethyl ketoxime, methyl isobutyl ketoxime, cyclohexanone oxime, acetoxime, diacetyl monoxime, or benzophenone oxime; an acid amide type blocking material such as acetanilide, ε-caprolactam, or γ-butyrolactam; an active methylene containing blocking material such as dimethyl malonate or methyl acetoacetate; a mercaptan type blocking material such as butyl mercaptan; an imide type blocking material such as succinic imide or maleic imide; an imidazole type blocking material such as imidazole or 2-methylimidazole; a urea type blocking material such as urea or thiourea; an amine type blocking material such as diphenylamine or aniline; and an imine type blocking material such as ethylene imine or polyethylene imine. Among these, the oxime type blocking material is preferred.

The image formation layer in the invention may contain a water-soluble material. Examples of the water-soluble material include the following compounds.

### [Water-Soluble Polymer]

Examples of the water-soluble material include a known water-soluble polymer, which is soluble in an aqueous solution having a pH of 4-10.

Typical examples of the water-soluble polymer include polysaccharides, polyethylene oxide, polypropylene oxide, polyvinyl alcohol, polyethylene glycol (PEG), polyvinyl ether, polyacrylic acid, polyacrylic acid salt, polyacrylamide, and polyvinyl pyrrolidone.

Among these, polysaccharides, polyacrylic acid, polyacrylic acid salt, polyacrylamide, and polyvinyl pyrrolidone are preferred.

Examples of the polysaccharides include starches, celluloses, polyuronic acid and pullulan. Among these, cellulose derivatives such as a methyl cellulose salt, a carboxymethyl cellulose salt and a hydroxyethyl cellulose salt are preferred, and a sodium or ammonium salt of carboxymethyl cellulose is more preferred.

The polyacrylic acid, polyacrylic acid salt, and polyacrylamide preferably have a molecular weight of 3,000-1,000,000, and more preferably have a molecular weight of 5,000-500,000.

Of these, polyacrylic acid salt such as sodium polyacrylate is most preferred. The polyacrylic acid salt efficiently works as a hydrophilization agent of the hydrophilic layer, and enhance hydrophilicity of a hydrophilic layer surface which is revealed on on-press development.

### [Oligosaccharides]

As the water-soluble material, oligosaccharides can be used other than the water-soluble polymers described above.

Examples of the oligosaccharides include raffinose, trehalose, maltose, galactose, sucrose, and lactose, and trehalose is especially preferred.

### [Another Material Optionally Contained in an Image Formation Layer]

The image formation layer can contain a light-to-heat conversion material for the image formation layer, and the foregoing similar light-to-heat conversion material can be utilized as the material.

It is desired that in the case of the infrared absorbing dye contained in the image formation layer, this content is adjusted considering color density of the layer or contamination of a printing press on on-press development. However, the content of the infrared absorbing dye in the image formation layer is preferably at least 0.001 g/m² and less than 0.2 g/m², and more preferably al least 0.001 g/m² and less than 0.05 g/m².

The following metal and metal compounds are preferably employed as the light-to-heat conversion material for the image formation layer.

Any metal may be used as the metal, provided that a particle diameter is at most 0.5 μm, and more preferably at most 100 nm, and still more preferably at most 50 nm. The metal may have any configuration such as spherical, flaked, needle shaped. Colloidal metal particles (Ag, Au and the like) are particularly preferred.

A material that exhibits black in the visible region or a material which is, itself, conductitve or semi-conductive may be used as the metal oxide.

Examples of the former include black iron oxide (Fe₃O₄) and black composite metal oxide containing two kinds of metals.

Examples of the latter include SnO₂ (ATO) that has doped Sb, In₂O₃ (ITO) that has added Sn; TiO₂, and TiO which has reduced TiO₂ (oxidized titanium nitride or generally titanium black).

Also usable is a core material (BaSO₄, TiO₂, 9Al₂O₃.2B₂O, K₂O.nTiO₂ and so forth) covered by the foregoing metal oxides.

The particle diameter is at most 0.5 μm, more preferably at most 100 nm, and still most preferably at most 50 nm.

Of these light-to-heat conversion materials, black composite metal oxide containing at least two kinds of metals are more preferable.

Specifically, examples thereof include composite metal oxides formed from at least two metals selected from Al, Ti, Cr, Mn, Fe, Co, Ni, Cu, Zn, Sb and Ba. These may be produced by methods disclosed in Japanese Patent O.P.I. Publication No. 8-27393, Japanese Patent O.P.I. Publication No. 9-25126, Japanese Patent O.P.I. Publication No. 9-237570, Japanese Patent O.P.I. Publication No. 9-241529 and Japanese Patent O.P.I. Publication No. 10-231441.

As the composite metal oxide of the present invention, Cu—Cr—Mn system composite metal oxide or Cu—Fe—Mn system composite metal oxide complex is particularly preferable. In the case of the Cu—Cr—Mn system, the process disclosed in Japanese Patent O.P.I. Publication No. 8-27393 is preferably conducted to reduce a hexavalent chromium elution. The coloring with respect to the addition amount of the composite metal oxide, or in other words, the light-to-heat conversion efficiency is favorable.

These composite metal oxides preferably have an average primary particle diameter of at most 1 μm, and more preferably an average primary particle diameter of 0.01-0.5 μm. When the average primary particle diameter is at most 1 μm, the light-to-heat conversion capability with respect to the addition amount is more favorable, and when the average primary particle diameter is within the range of 0.01-0.5 μm, the light-to-heat conversion capability with respect to the addition amount is even more favorable.

However, the light-to-heat conversion capability with respect to the addition amount is largely influenced by the dispersion degree of particles, and the better dispersion, the higher the light-to-heat conversion capability is.

Accordingly, prior to adding these composite metal oxide particles into the coating solution for the layer, they are preferably dispersed separately by a known method, and are formed as a dispersion (paste). An average primary particle diameter of less than 0.01 is not preferable because of difficulty of dispersing. Any dispersant is appropriately usable for dispersion. The addition amount of the dispersant is preferably 0.01-5% by weight, based on the composite metal oxide particles, and more favorably 0.1-2% by weight.

A surfactant can also be contained in an image formation layer. Si based or F based surfactants can be employed, but a surfactant containing a Si element is preferably utilized, since printing contamination tends hardly to be generated. The content of the surfactant is preferably 0.01-3% by weight, based on the entire hydrophilic layer (solid content in the case of a coating solution), and more preferably 0.03-1% by weight.

### (Protective Layer)

A protective layer may also be provided on an image formation layer. The material used for the protective layer is preferably a water-soluble resin or a water-dispersible resin.

Further, hydrophilic overcoat layers disclosed in Japanese Patent O.P.I. Publication Nos. 2002-019318 and 2002-086948 are preferably usable.

The coating amount of the protective layer is preferably 0.01-10 g/m², more preferably 0.1-3 g/m² and still more preferably 0.2-2 g/m².

### (Imagewise Exposure)

The imagewise exposure in the present invention is carried out via irradiation with laser light, depending on image data obtained from the surface having an image formation layer of a planographic printing plate material.

In the present invention, the imagewise exposure is preferably scanning exposure, which is carried out employing a laser which can emit light having a wavelength of infrared and/or near-infrared regions, that is, a wavelength of 700-1500 nm.

As the laser, a gas laser can be used, but a semi-conductor laser, which emits light having a near-infrared region wavelength, is preferably used for scanning exposure.

A device suitable for the scanning exposure which is usable in the present invention may be any device capable of forming an image on the printing plate material surface according to image signals from a computer employing a semiconductor laser.

Generally, the following scanning exposure processes are provided.

(1) A process in which a plate precursor provided on a fixed horizontal plate is scanning exposed in two dimensions, employing one or several laser beams.

(2) A process in which the surface of a plate precursor provided along the inner peripheral wall of a fixed cylinder is subjected to scanning exposure in the rotational direction (in the main scanning direction) of the cylinder, employing one or several laser beams located inside the cylinder, while moving the lasers in the normal direction to the rotational direction of the cylinder (in the sub-scanning direction).

(3) A process in which the surface of a plate precursor provided along the outer peripheral wall of a fixed cylinder is subjected to scanning exposure in the rotational direction (in the main scanning direction) of the cylinder, employing one or several laser beams located outside the cylinder, while moving the lasers in the normal direction to the rotational direction of the cylinder (in the sub-scanning direction).

The plate inspection is conducted for the planographic printing plate material imagewise exposed to light, if desired.

A printing process is subsequently conducted in the case of a planographic printing plate material subjected particularly to no developing treatment, for example.

In this case, removal of non-image portion (unexposed portion) of the image formation layer on a printing press is carried out by contacting the dampening roller and the inking roller while the plate cylinder is rotating, according to the sequence described below or according to other appropriate sequences. The supplied amount of dampening water may be adjusted to be greater or smaller than the amount ordinarily supplied in printing, and the adjustment may be carried out stepwise or continuously.

(1) A dampening roller is brought into contact with the image formation layer of a printing plate material on the plate cylinder during one to several tens of rotations of the plate cylinder, and then an inking roller brought into contact with the image formation layer during the next one to tens of rotations of the plate cylinder. Thereafter, printing is carried out.

(2) An inking roller is brought into contact with the image formation layer of a printing plate material on the plate cylinder during one to several tens of rotations of the plate cylinder, and then a dampening roller brought into contact with the image formation layer during the next one to tens of rotations of the plate cylinder. Thereafter, printing is carried out.

(3) An inking roller and a dampening roller are brought into contact with the image formation layer of a printing plate material on the plate cylinder during one to several tens of rotations of the plate cylinder. Thereafter, printing is carried out.

### EXAMPLE

The present invention will now be described in detail referring to examples, however, the present invention is not limited thereto. Incidentally, “parts” in the description represents “parts by weight”, unless otherwise mentioned.

### Example 1

### Preparation of Substrate

A 0.24 mm thick aluminum plate (material 1050, refining H16) was immersed in an aqueous 1% by weight sodium hydroxide solution at 50° C. to conduct a dissolution treatment so as to give a dissolution amount of 2 g/m², washed with water, then immersed in an aqueous 0.1% by weight hydrochloric acid solution at 25° C. for 30 seconds to neutralize, and subsequently washed with water.

Next, the aluminum plate was subjected to an electrolytic surface roughening treatment in an electrolytic solution containing 10 g/liter of hydrochloric acid and 0.5 g/liter of aluminum at a peak current density of 50 A/dm² employing an alternating current with a sine waveform.

The distance between the plate surface and the electrode was set to 10 mm in this case. The electrolytic surface roughening treatment was divided into 12 processes, in which the quantity of electricity used in one process (at a positive polarity) was 40 C/dm², and the total quantity of electricity used (at a positive polarity) was 480 C/dm². Standby time of 5 seconds, during which no surface roughening treatment was carried out, was provided after each of the processes of electrolytic surface roughening treatment.

The resulting aluminum plate was subsequently immersed in an aqueous 1% by weight sodium hydroxide solution at 50° C. and etched to give an aluminum etching amount (including smut produced on the surface) of 1.2 g/m², washed with water, neutralized in an aqueous 10% by weight sulfuric acid solution at 25° C. for 10 seconds, and washed with water. Subsequently, the aluminum plate was subjected to anodizing treatment in an aqueous 20% by weight sulfuric acid solution at a constant voltage of 20 V, in which a quantity of electricity of 150 C/dm² was supplied, and washed with water.

The washed surface of the plate was squeegeed, and the plate was immersed in an aqueous 1% by weight sodium dihydrogen phosphate solution at 70° C. for 30 seconds, washed with water, and dried at 80° C. for 5 minutes to obtain substrate 1.

Substrate 1 had an Ra of 460 nm (measured at a magnification of 40 times, employing RST Plus, produced by WYKO Corporation).

### [Light-to-Heat Conversion Material Provided in Anodization Film Pores]

Substrate 1 was subjected to an alternating current constant-voltage process conducting in a metal ion-containing electrolyte for 90 seconds as an electrolytic coloring method to precipitate metal particles in anodization film pores.

Stannous sulfate is employed as the metal ion-containing electrolyte, and coloring was carried out under the following electrolysis condition.

Electrolyte: 10 g/liter of stannous sulfate, 10 g/liter of sulfuric acid and 5 g/liter of catechol

A treatment temperature of 31° C.

A voltage of 15 V

A slow start-up in 15 minutes

### [Colorants Provided in Anodization Film Pores]

Next, an aqueous 7.5 g/liter solution of TAC RED-SCH (Red 106) produced by Okuno Chemical Industries Co., Ltd. was adjusted to pH 5.0 using sodium acetate and acetic acid, and a substrate was immersed in the resulting solution maintained at 55° C. for 10 minutes while stirring to color the anodization film.

### [Sealing Treatment]

An aqueous solution having the following composition was adjusted to pH 5.5, and subsequently heated to 85° C. The above-described colored substrate was immersed for 15 minutes while stirring to conduct a sealing treatment.

5 g/liter of nickel acetate

1 g/liter of cobalt acetate

8 g/litter of boric acid

Reflection density on the aluminum substrate surface after the sealing treatment was 1.8. As for the density measurement, the reflection density of black (K) was determined by using the values measured under the filter condition of D65 and absolute white as a white base accompanied with a field of view of 2° and density standard of Status-T, employing a spectrodensitometer Spectrolino, produced by GretagMacbeth Ltd.

Next, an aqueous solution of 0.1% by weight carboxymethyl cellulose 1150 (produced by Daicel Chemical Industries, Ltd.) was immersed at 75° C. for 30 seconds while stirring, then washed with water, and dried.

### [Preparation of Planographic Printing Plate Material]

### [Printing Plate Material 1]

After the material with the following composition was sufficiently mixed while stirring, the concentration was adjusted to be appropriately diluted with pure water, and the system was filtrated to obtain a coating solution of the following image formation layer (1) composition having a solid content of 2.5% by weight.

Next, The coating solution of image formation layer (1) was coated onto a substrate employing a wire bar so as to give a coating amount of 0.4 g/m² after drying, followed by drying at 50° C. for 3 minutes.

Next, an aging treatment was conducted at 40° C. for 24 hours to obtain printing plate material 1.

The ratio of weight parts represents the weight ratio in a solid content after drying.

### Coating Solution Composition of Image Formation Layer (1)

| | |
|---|---|
| Thermosensitive material: Water-dispersible | 155 parts |
| block type polyurethane prepolymer solution | |
| (Takenate WB-700, produced by Mitsui | |
| Chemicals Polyurethanes, Inc. | |
| solid content: 44% by weight) | |
| Water-soluble resin: Aqueous solution of | 40 parts |
| sodium polyacrylate, Aqualic DL522, | |
| produced by Nippon Shokubai Co., Ltd. | |
| (solid content: 10% by weight) | |
| Infrared absorbing dye: Aqueous 1% by weight | 800 parts |
| solution of ADS830WS (produced by American | |
| Dye Source, Inc.) | |
| Layered mineral particles: Hydrophilic 5% | 400 parts |
| Smectite SWN aqueous solution, produced by | |
| Co-op Chemical Co., Ltd. | |

### [Image Formation Via Infrared Laser Exposure]

A printing plate material was wound around an exposure drum, and fixed. Images were formed at a resolution of 2400 dpi (“dpi” means a dot number per 1 inch, i.e., 2.54 cm) and at a line number of 175 with 400 mJ/cm² of exposure energy, employing a 830 nm wave length laser with a spot diameter of 18 μm during exposure. The image pattern used for the exposure includes a solid image and a dot image with a dot area of 1-99%.

### [Printing Method]

Printing was carried out employing a printing press, DAIYA 1F-1 produced by Mitsubishi Heavy Industries Ltd., accompanied with coated paper, a dampening solution of a 2% by weight solution of Astromark 3 (produced by Nikken Kagaku Kenkyusyo Co., Ltd.) and printing ink (Toyo King Hyunity Magenta, produced by Toyo Ink Manufacturing Co. Ltd.). The printing plate material was mounted on a plate cylinder of a printing press after exposure, and printing was conducted in the same initial printing sequence as in a conventional PS plate. Density at solid image portions of prints was adjusted so as to give 1.4 (in the same density measurement condition as in the foregoing).

### (Evaluation)

### [Color Contamination]

A printing plate material was printed by a printing press to print 100 prints. The L*a*b* value of non-image portions of the 10^{th} printing paper sheet from the initial printing was measured employing a spectrodensitometer Spectrolino, manufactured by GregMacbeth Ltd. to determine color difference (ΔE) from the L*a*b* value of a printing paper sheet before printing for evaluation of color contamination, and this color difference was defined as color reproduction. Practically with no problem at 0.6 or less.

After printing of the printing plate material was finished, the printing press was cleaned, and printing ink and dampening water were newly changed.

### [Evaluation of Visualization Property]

After image formation via infrared laser exposure, a printing plate material was observed under a standard light source of Prooflite Luminaire PLD50-440 (for reflection), produced by GretagMacbeth Ltd. to observe images at dot step portions.

Distinguishability of the difference in gradation between different dot % steps in this case was evaluated.

### Evaluation Criteria

5: 5% step difference of dot gradation difference % in a dot area of 1-99% is visually distinguishable.

4: 5% step difference of dot gradation difference % in a dot area of 5-95% is visually distinguishable.

3: 20% step difference of dot gradation difference % in a dot area of 10-90% is visually distinguishable.

2: Step difference between a dot area of 0% (unexposed region), a dot area of 50% and a dot area of 100% (solid image) is visually distinguishable.

1: Step difference between a dot area of 0% (unexposed region) and a dot area of 100% (solid image) is visually distinguishable.

### [Printing Durability]

As to each printing plate material subjected to printing from initial printing to 20,000 prints, the number of prints in which a small lacking portion with no ink adhesion was first generated in a dot area of 3% was visually observed employing a loupe at a magnification of 20 times. Results are shown in Table 1.

### Example 2

Printing plate material 2 was prepared similarly to preparation of printing plate material 1, except that a sealing treatment was removed.

The same evaluation as in Example 1 was made employing printing plate material 2. Results are shown in Table 1.

### Example 3

Printing plate material 3 was prepared similarly to preparation of printing plate material 1, except that a process in which a light-to-heat conversion material was provided in anodization film pores was removed. Results are shown in Table 1.

### Example 4

Printing plate material 4 was prepared similarly to preparation of printing plate material 1, except that a sealing treatment and a process in which a light-to-heat conversion material was provided in anodization film pores were removed. Results are shown in Table 1.

### Comparative Example 1

Printing plate material 5 was prepared similarly to preparation of printing plate material 1, except that a sealing treatment and a process in which a colorant was provided in anodization film pores were removed.

### Comparative Example 2

Printing plate material 6 was prepared similarly to preparation of printing plate material 1, except that a sealing treatment, a process in which a light-to-heat conversion material was provided in anodization film pores, and a process in which a colorant was provided in anodization film pores were removed.

As is clear from Table 1, it is to be understood that the image forming method of the present invention is capable of on-press developing, and also provided is a printing method exhibiting an excellent exposure visualization property, excellent plate inspection together with excellent color reproduction coupled with no printing ink contamination and excellent printing durability.

TABLE 1

| | | In anodization | | | | | |
|---|---|---|---|---|---|---|---|
| | | film pores | | | | Color | |
| | | | Light-to- | | | dif- | |
| | | | heat | | | fer- | |
| | | Dye | conversion | Sealing | | ence | Printing |
| | *1 | coloring | material | treatment | *2 | (ΔE) | durability |
| Ex. 1 | 1 | Presence | Presence | Conducted | 5 | Less | 20,000 |
| | | | | | | than | prints |
| | | | | | | 0.1 | or more |
| Ex. 2 | 2 | Presence | Presence | Not | 5 | 0.4 | 20,000 |
| | | | | conducted | | | prints |
| Ex. 3 | 3 | Presence | Absence | Conducted | 4 | Less | 15,000 |
| | | | | | | than | prints |
| | | | | | | 0.1 | |
| Ex. 4 | 4 | Presence | Absence | Not | 3 | 0.4 | 14,000 |
| | | | | conducted | | | prints |
| Comp. | 5 | Absence | Presence | Conducted | 1 | Less | 19,000 |
| 1 | | | | | | than | prints |
| | | | | | | 0.1 | |
| Comp. | 6 | Absence | Absence | Not | 1 | Less | 9,000 |
| 2 | | | | conducted | | than | prints |
| | | | | | | 0.1 | |

Ex.: Example,
Comp.: Comparative example,
*1: Printing plate material,
*2: Visualization property

### POSSIBILITY OF INDUSTRIAL USE

The foregoing structures of the present invention can provide a method of forming an exposure visualization image of a planographic printing plate material in which printing of the planographic printing plate material is capable of on-press printing, and also provided is a printing method exhibiting an excellent exposure visualization property, excellent plate inspection together with excellent color reproduction coupled with no printing ink contamination and excellent printing durability.

1. A method of forming an exposure visualization image of a planographic printing plate material comprising the step of:
imagewise exposing the planographic printing plate material comprising an aluminum support having anodization film pores on a surface of the aluminum support and provided thereon, an image formation layer to form the visualization image,
wherein the aluminum support comprises a colorant producing color change via heat, in the anodization film pores.

2. The method of claim 1,
wherein the aluminum support further comprises a light-to-heat conversion material in the anodization film pores.

3. The method of claim 2,
wherein a sealing treatment is conducted after containing the colorant and the light-to-heat conversion material in the anodization film pores.

4. The method of claim 1,
wherein the image formation layer is a thermosensitive image formation layer.

5. An aluminum support utilized for the method of claim 1.

6. A planographic printing plate material utilized for the method of claim 1.
